(19) United States
(12) Patent Application Publication
(10) Pub. No.: US 2012/0250434 A1
(43) Pub. Date: Oct. 4, 2012

(54) METHOD OF ACCELERATING WRITE TIMING CALIBRATION AND WRITE TIMING CALIBRATION ACCELERATION CIRCUIT IN SEMICONDUCTOR MEMORY DEVICE

(75) Inventor: Won-Hyung SONG, Osan-si (KR)

(73) Assignee: SAMSUNG ELECTRONICS CO., LTD., Suwon-si (KR)

(21) Appl. No.: 13/435,333

(22) Filed: Mar. 30, 2012

(30) Foreign Application Priority Data
Mar. 30, 2011 (KR) 10-2011-0029042

(51) Int. Cl. G11C 8/18; G11C 7/00

(52) U.S. Cl. 365/193; 365/191

(57) ABSTRACT

A method of accelerating write timing calibration and a write timing calibration acceleration circuit in a semiconductor memory device are disclosed. The write timing calibration acceleration circuit includes a phase difference detection unit and a detection data output unit. The phase difference detection unit detects a phase difference between a first signal and a second signal applied for a write timing calibration. The detection data output unit outputs detection data corresponding to the detected phase difference through a data output line. According to the write timing calibration acceleration circuit of the inventive concept, a time taken to perform a write timing calibration is reduced, thereby minimizing boot up time and power consumption.

### CROSS-REFERENCE TO RELATED APPLICATIONS

This U.S. non-provisional patent application claims priority under 35 U.S.C. §119 from Korean Patent Application No. 10-2011-0029042, filed on Mar. 30, 2011, the entire contents of which are hereby incorporated herein by reference.

### BACKGROUND

The present inventive concept herein relates to semiconductor devices, and more particularly, to a method of accelerating a write timing calibration and a write timing calibration acceleration circuit.

Generally, a volatile semiconductor memory device such as a dynamic random access memory (DRAM) may write data being applied from a controller of a system in an assigned memory storage region.

When a DRAM is used in a data processing device such as a computer, it may be used in the form of memory module such that a plurality of DRAMs are mounted on a printed circuit board. As a connection structure of a command signal of a memory module becomes a fly-by type, a command input time and an effective write data input time may be different in every DRAM of the memory module.

Thus, to find an optimum data write timing, a timing calibration process called a write leveling may be performed between a controller and a DRAM.

### SUMMARY

Exemplary embodiments of the inventive concept provide a method of accelerating a write timing calibration. The method may include detecting a phase difference between a first signal and a second signal applied for a write timing calibration; and outputting detection data corresponding to the detected phase difference through a data output line.

Exemplary embodiments of the inventive concept also provide a write timing calibration acceleration circuit. The write timing calibration acceleration circuit may include a phase difference detection unit which detects a phase difference between a first signal and a second signal applied for a write timing calibration; and a detection data output unit which outputs detection data corresponding to the detected phase difference through a data output line.

### BRIEF DESCRIPTION OF THE FIGURES

The foregoing and other features and advantages of the inventive concept will be apparent from the more particular description of preferred aspects of the exemplary embodiments, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 is a block diagram illustrating a connection structure between a controller and a semiconductor memory device in accordance with exemplary embodiments of the inventive concept.

FIG. 2 is an exemplary embodiment of a timing calibration acceleration circuit illustrated in FIG. 1.

FIG. 3 is another exemplary embodiment of a timing calibration acceleration circuit illustrated in FIG. 1.

FIG. 4 is still another exemplary embodiment of a timing calibration acceleration circuit illustrated in FIG. 1.

FIGS. 5A to 5C are drawings illustrating a generation of binary data in accordance with a phase difference detection in exemplary embodiments of the inventive concept.

FIG. 6A is a detailed circuit diagram embodying FIG. 2.

FIG. 6B is an operation timing diagram in accordance with FIG. 6A.

FIG. 7 is an operation control flow chart in accordance with some exemplary embodiments of the inventive concept.

FIG. 8 is a block diagram illustrating an exemplary embodiment of the inventive concept connected to a memory controller.

FIG. 9 is a block diagram illustrating an exemplary embodiment of the inventive concept adopted in an electronic system.

FIG. 10 is a block diagram illustrating an exemplary embodiment of the inventive concept adopted in a computing system.

### DETAILED DESCRIPTION

Exemplary embodiments of the inventive concept will be described below in more detail with reference to the accompanying drawings. These exemplary embodiments of the inventive concept may, however, be embodied in different forms and should not be constructed as limited to the exemplary embodiments set forth herein. Rather, these exemplary embodiments are provided so that this disclosure will be thorough and complete, and will fully convey the scope of the inventive concept to those skilled in the art. Like numbers refer to like elements throughout.

It will be understood that when an element is referred to as being “connected” or “coupled” to another element, it can be directly connected or coupled to the other element or intervening elements may be present. In some drawings, a connection relation between elements is only for an effective description of technology contents and other devices or other function blocks may be further included in the drawings.

Each exemplary embodiment of the inventive concept may include a complementary embodiment and the full description of basic operations of read or write in a dynamic random access memory (DRAM) will be omitted for brevity.

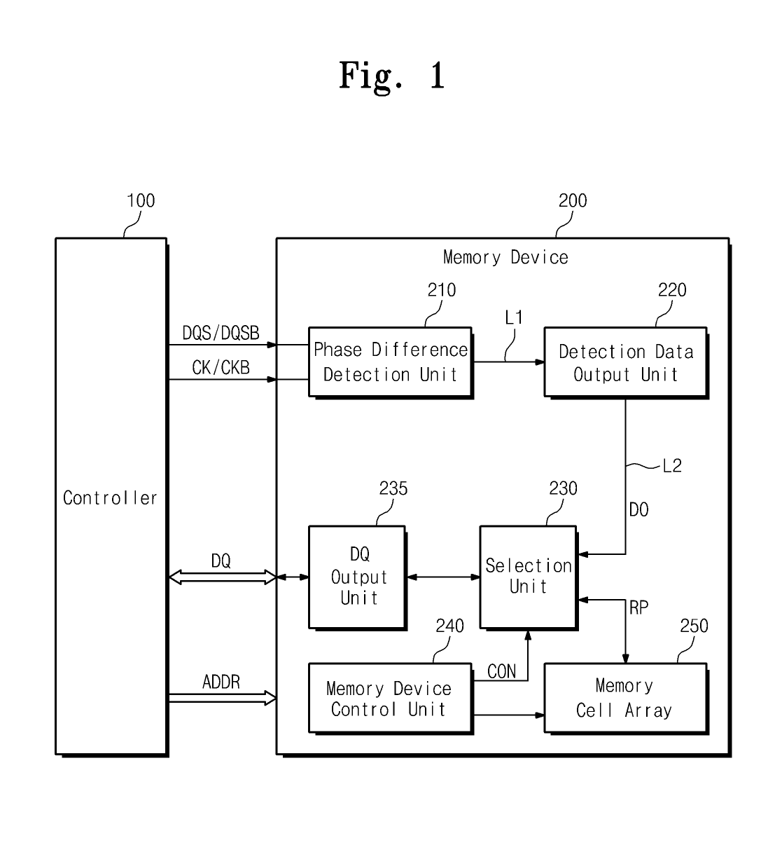

FIG. 1 is a block diagram illustrating a connection structure between a controller and a semiconductor memory device in accordance with an exemplary embodiment of the inventive concept.

Referring to FIG. 1, a semiconductor memory device 200 may include a memory device control unit 240, a memory cell array 250, a selection unit 230 and DQ output unit 235. The semiconductor memory device 200 may also include a phase difference detection unit 210 and a detection data output unit 220 as a write timing calibration acceleration circuit.

The phase difference detection unit 210 detects a phase difference between a first signal DQS and a second signal CK applied for a write timing calibration and then outputs the detected phase difference to a line (L1). The detection data output unit 220 connected to the line L1 generates detection data D0 corresponding to the detected phase difference and then it outputs the phase difference to a line L2. The detection data D0 is output to a data output DQ through the selection unit 230 and the DQ output unit 235.

The first signal DQS is a data strobe signal and it may be output as a data strobe signal DQS and a complimentary data strobe signal DQSB from the controller 100. That is, when necessary, the data strobe signal may be provided in the form of a differential signal.

Similarly, the second signal CK is a clock signal and it may be output as a clock signal CK and a complimentary clock signal CKB from the controller 100. That is, when necessary, the clock signal may be provided in the form of differential signal.

When a write timing calibration is performed, the memory device control unit 240 applies a selection control signal CON that makes the selection unit 230 to select the detection data D0 applied through the line L2 to the selection unit 230. The detection data D0 may be represented by binary data which is proportional to a degree of the detected phase difference. The detection data D0 is output to a DQ bus through the DQ output unit 235. As soon as the controller 100 receives the detection data D0, it may check a phase difference between the first signal DQS and the second signal CK and thereby a time taken to perform a write timing calibration may be reduced or minimized. To verify a write timing calibration, after delaying the first signal DQS by a value of the detection data D0 at once, it may be applied to the phase difference detection unit 210. In this case, the detection data D0 received by the DQ bus may be data representing that a phase difference between the two signals does not exist.

In this way, a write timing calibration may be performed by applying a signal one time without sequentially delaying a data strobe signal by a specific unit delay.

Since a timing calibration process called a write leveling is performed at once to find the optimum data write timing, an effective write data input time may be quickly detected.

In a read operation the data stored in a memory cell of the memory cell array 250 is output through the DQ bus, the controller 100 applies an address signal indicating an address of memory cell through an address bus ADDR. In this case, the selection unit 230 selects a read pass RP connected to the memory cell array 250 in response to a selection control signal CON.

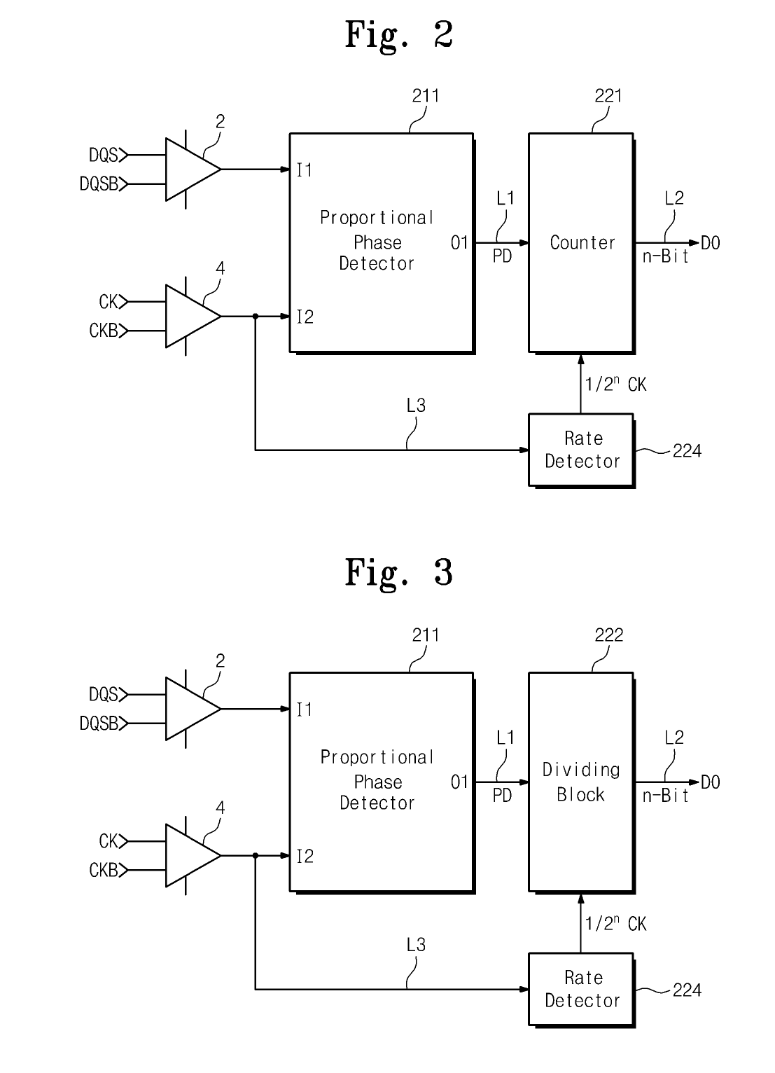

FIG. 2 is an exemplary embodiment of a timing calibration acceleration circuit illustrated in FIG. 1.

Referring to FIG. 2, a write timing calibration acceleration circuit includes a proportional phase detector 211, a counter 221 and a rate detector 224. The proportional phase detector 211 is an exemplary embodiment of the phase difference detection unit 210 of FIG. 1 and the counter 221 and the rate detector 224 are an exemplary embodiment of the detection data output unit 220 of FIG. 1. Reference numerals 2 and 4 in FIG. 2 represent receiving buffers respectively.

The first signal (e.g., data strobe signal DQS) is applied to the receiving buffer 2 in the form of differential signal, and then is buffered. The data strobe signal DQS output from the receiving buffer 2 is applied to a first input terminal I1 of the proportional phase detector 211.

The second signal (e.g., clock signal CK) is applied to the receiving buffer 4 in the form of differential signal, and then is buffered. The clock signal CK output from the receiving buffer 4 is applied to a second input terminal 12 of the proportional phase detector 211.

The rate detector 224 may be connected to an output line L3 of the receiving buffer to generate a divided clock signal (½n CK) obtained by dividing the clock signal CK by 2n. Herein, n is a natural number.

The proportional phase detector 211 detects a phase difference between the data strobe signal DQS applied to calibrate write timing and the clock signal CK. That is, a value of detected phase difference PD generated on the line L1 may be in proportion to a degree of the phase difference.

The counter 221 counts the detected phase difference PD by the divided clock signal (½n CK) of the clock signal. Thus, a detected data D0 generated on the output line L2 of the counter 221 may be n-bit binary data (n is a natural number of two or more). In this case, the number of bits of the binary data may be one of 4 bit, 8 bit and 16 bit.

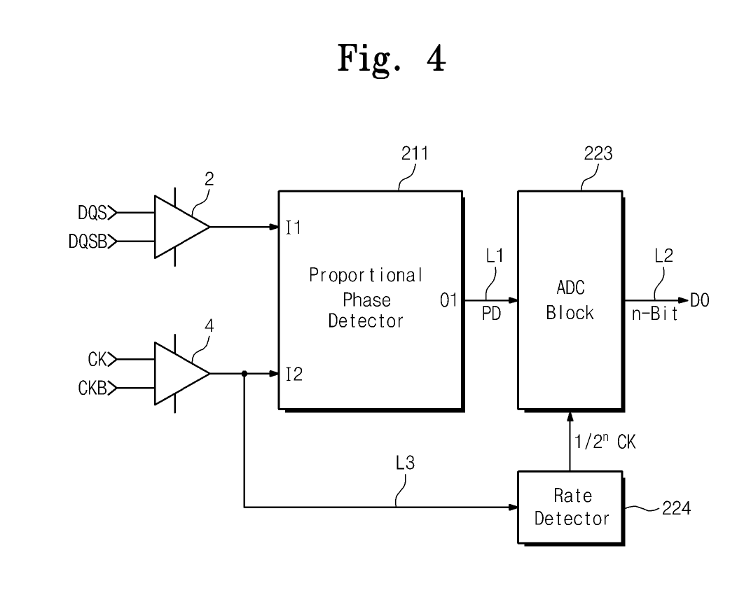

FIG. 3 is another exemplary embodiment of a timing calibration acceleration circuit illustrated in FIG. 1.

In FIG. 3, the detection data output unit 220 of FIG. 1 is embodied by a dividing block 222 and a rate detector 224. The dividing block 222 divides the detected phase difference by a divided clock signal of the clock signal and the rate detector 224 generates the divided clock signal by dividing the clock signal. The dividing block 222 may include a divider circuit and an output unit outputting a result divided by the divider circuit in the form of binary data.

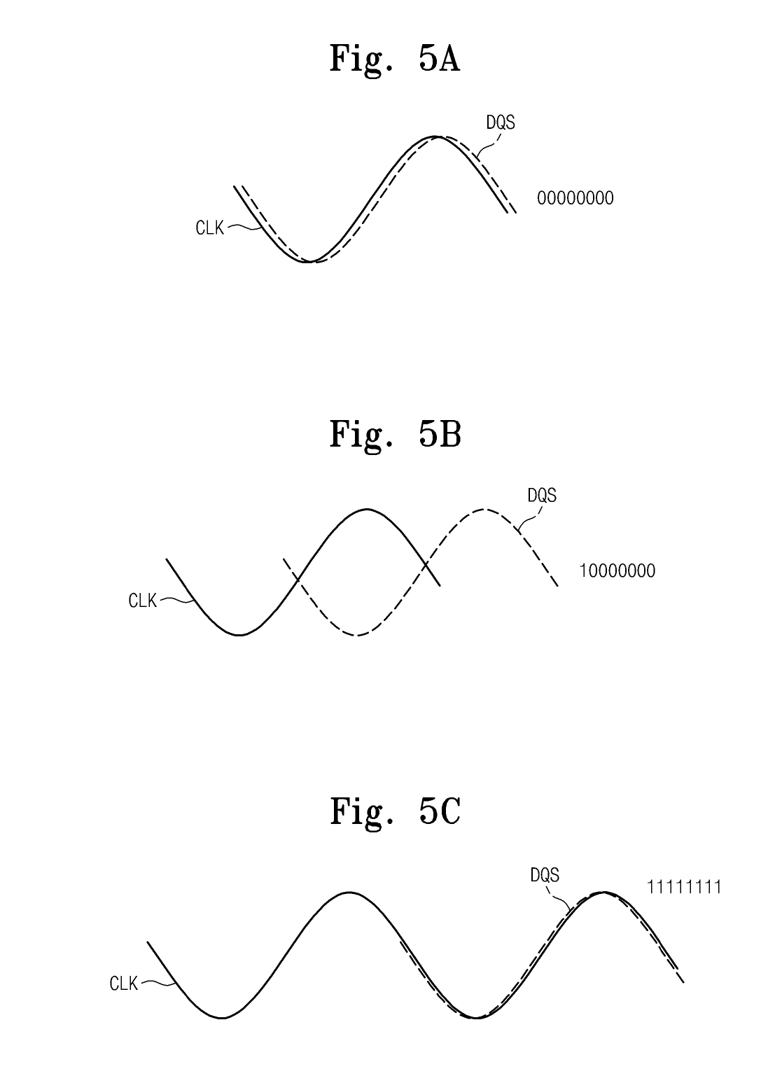

FIG. 4 is still another exemplary embodiment of a timing calibration acceleration circuit illustrated in FIG. 1.

In FIG. 4, the detection data output unit 220 of FIG. 1 is embodied by an analog to digital converting block 223 and a rate detector 224. The analog-digital converting block 223 performs an analog-digital conversion on the detected phase difference by a divided clock signal of the clock signal and the rate detector 224 generates the divided clock signal by dividing the clock signal. The analog-digital converting block 223 may include an analog-digital converter (ADC) and an output unit outputting an output of the analog-digital converter in the form of binary data.

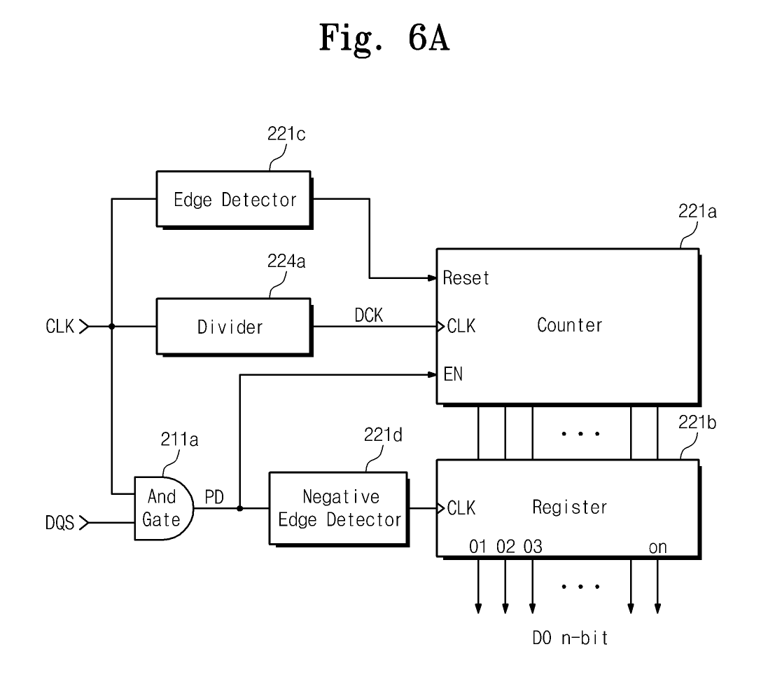

FIGS. 5A to 5C are drawings illustrating a generation of binary data in accordance with a phase difference detection in some exemplary embodiments of the inventive concept.

Referring to FIG. 5A, a phase of the data strobe signal is the same with a phase of the clock signal. In this case, a detected data, if it is 8 bit, may be generated in binary data of “00000000”. That is, a phase difference between the two signals is zero.

Referring to FIG. 5B, the data strobe signal and the clock signal have a phase difference of half period. In this case, a detected data, if it is 8 bit, may be generated in binary data of “10000000”. That is, a phase difference between the two signals is 180°.

Referring to FIG. 5C, the data strobe signal and the clock signal have a phase difference of one period. In this case, a detected data, if it is 8 bit, may be generated in binary data of “11111111”. That is, a phase difference between the two signals is 360°.

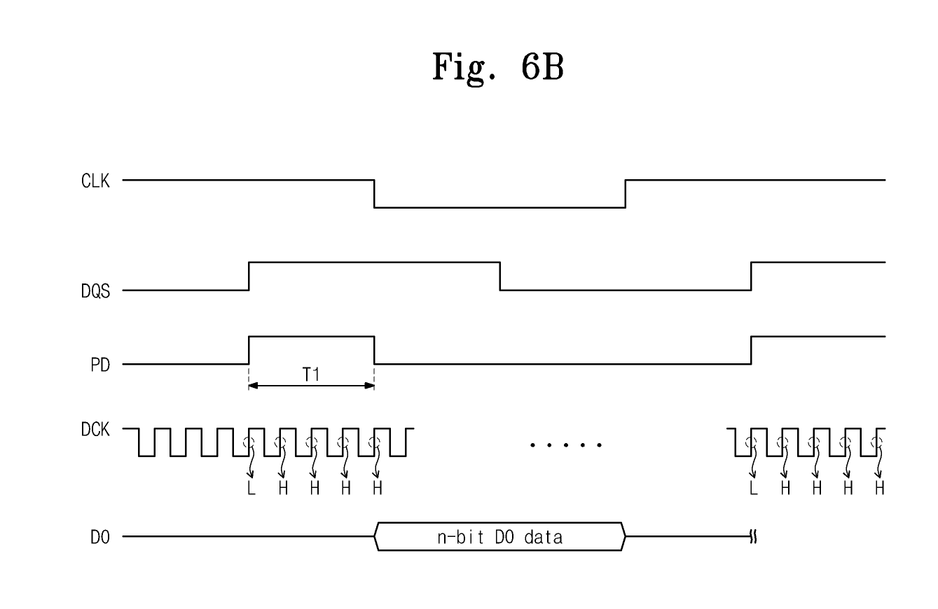

FIG. 6A is a detailed circuit diagram embodying FIG. 2.

In FIG. 6A, an AND gate 211a corresponds to the proportional phase detector 211 of FIG. 2 and a divider 224 corresponds to the rate detector 224a of FIG. 2. Also, a counter 221a, a register 221b, an edge detector 221c and a negative edge detector 221d correspond to the counter 221 of FIG. 2.

The counter 221a may include a clock input terminal CLK, an enable signal input terminal EN and a reset signal input terminal (Reset). A gating output PD of the AND gate 211a is applied to the enable signal input terminal EN. A divided clock DCK of the divider 224a is applied to the clock input terminal CLK and an edge detection output of the edge detector 221c is applied to the reset signal input terminal (Reset).

The receiving buffers 2 and 4 illustrated in FIG. 2 are omitted in FIG. 6A.

An exemplary embodiment is illustrated in FIG. 6B that a first signal (e.g., data strobe signal DQS) is applied to one input terminal of the AND gate 211a and a second signal (e.g., clock signal CK) is applied to the other input terminal of the AND gate 211a.

FIG. 6B is an operation timing diagram in accordance with FIG. 6A.

In the case that the data strobe signal DQS and the clock signal CK are applied with the timing illustrated in FIG. 6B, the AND gate 211 generates a gating output PD having a high state in a T1 section. The gating output PD is generated to have a high pulse in a section in which the data strobe signal DQS and the clock signal CK are in a high state. That is, the high pulse represents a phase difference detection signal.

The counter 221a counts a length of the section T1 by the divided clock. In FIG. 6B, a length of the section T1 corresponds to four periods of the divided clock DCK. Consequently, similar to FIG. 5B, in the case of 4 bit, binary data having a value of “1000” may be obtained.

In FIG. 6B, the detection data D0 is represented as series data of n bits. However, the detection data D0 may be parallel data output from output terminals of the register 221b at one time.

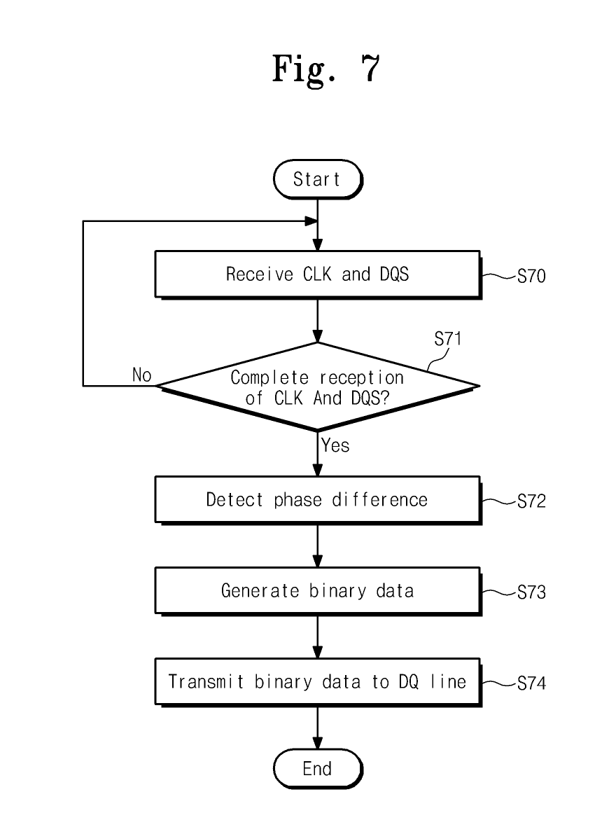

FIG. 7 is an operation control flow chart in accordance with exemplary embodiments of the inventive concept.

Referring to FIG. 7, in S70, the clock signal CLK and the data strobe signal DQS are received from the controller 100. In S71, it is checked whether a receiving operation of the CLK and the DQS is completed or not. If the receiving operation of the CLK and the DQS is completed, in S72, a phase difference detection is performed between the CLK and the DQS applied for a write timing calibration. If the phase difference detection is performed, in S73, detection data corresponding to the detected phase difference is generated in the form of binary data. In S74, the binary data is transmitted to the controller 100 through the data output DQ line. According to the write timing calibration acceleration method like FIG. 7, the controller 100 may recognize a phase difference between the clock signal CLK and the data strobe signal DQS right after receiving the detection data applied in the form of binary data. Since an operation of sequentially delaying the data strobe signal during a timing calibration procedure is not needed, a time taken to perform a write timing calibration may be reduced or minimized.

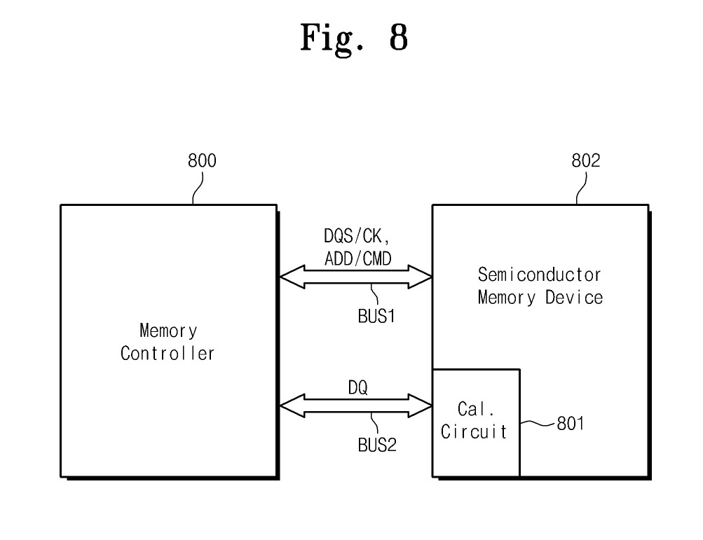

FIG. 8 is a block diagram illustrating an application example of the inventive concept connected to a memory controller.

Referring to FIG. 8, a semiconductor memory device 802 including a write timing calibration acceleration circuit 801 is connected to the memory controller 800 through buses BUS1 and BUS2. The BUS1 is a bus transmitting a data strobe signal DQS, a clock signal CK, an address ADD and a command CMD and the BUS2 is a data output DQ bus. Data output from the semiconductor memory device 802 and detected data corresponding to a phase difference detected according to some exemplary embodiments of the inventive concept are transmitted through the BUS2. When a boot up operation is performed, the memory controller 800 can calibrate a write timing right after receiving the detected data through the BUS2 after applying the data strobe signal DQS and the clock signal CK.

As illustrated in FIG. 8, if the semiconductor memory device 802 includes the write timing calibration acceleration circuit 801, a time taken to perform a write timing calibration in the memory controller 800 may be reduced or minimized. Thus, a boot up time of the whole system including the memory controller 800 may be minimized and a power may be greatly saved.

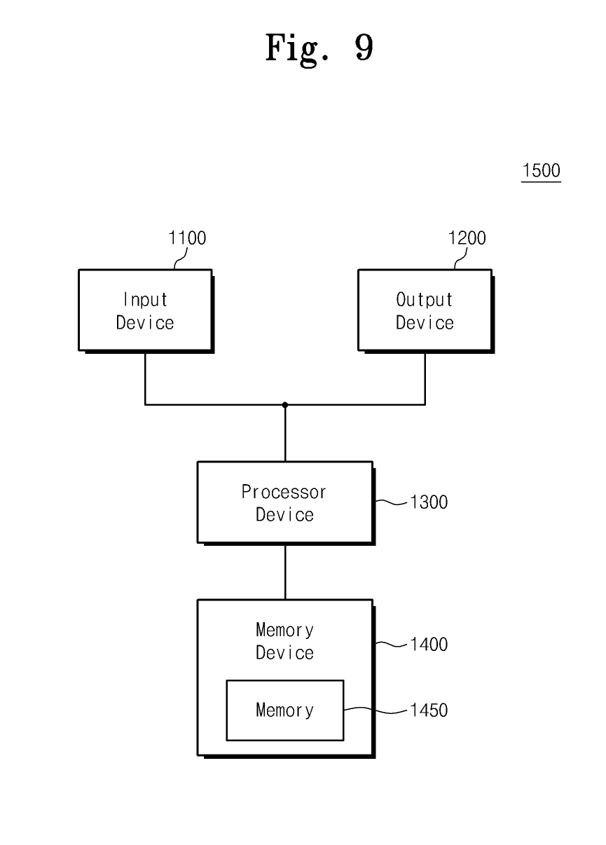

FIG. 9 is a block diagram illustrating an application example of the inventive concept adopted in an electronic system.

Referring to FIG. 9, an electronic system 1500 may include an input device 1100, an output device 1200, a processor device 1300 and a memory device 1400.

The memory device 1400 may include the write timing calibration acceleration circuit in accordance with an exemplary embodiment of the inventive concept. Herein, the memory device 1400 may include a conventional memory or a memory 1450 having a three dimensional laminated structure. The memory device 1400 may include a memory controller and the memory 1450 similar to FIG. 8. The write timing calibration acceleration circuit may be built in the memory 1450. The processor device 1300 controls the input device 1100, the output device 1200 and the memory device 1400 through corresponding interfaces respectively. In FIG. 9, if a write timing calibration acceleration circuit is adopted in the memory, a time taken to perform a write timing calibration in the memory device 1400 may be reduced or minimized. Thus, a boot up time of the memory device 1400 may be minimized and a power may be greatly saved. Accordingly, operation performance of the electronic system may be improved.

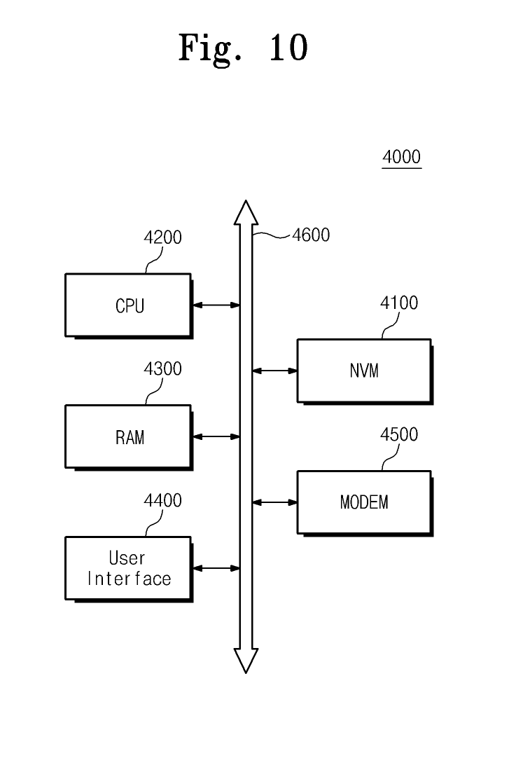

FIG. 10 is a block diagram illustrating an application example of the inventive concept adopted in a computing system.

Referring to FIG. 10, a computing system 4000 may include a central processing unit (CPU) 4200, a random access memory (RAM) 4300, a user interface 4400, a MODEM 4500 such as a baseband chipset and a nonvolatile memory (NVM) 4100 that are electrically connected to a system bus 4600.

If the computing system 4000 is a mobile device, a battery (not illustrated) for supplying an operation voltage of the computing system 4000 may be additionally provided.

Although not illustrated in the drawing, an application chipset, a camera image processor (CIP) and a mobile DRAM may be further provided to the computing system 4000. The nonvolatile memory 4100 may be embodied by, for example, a solid state drive/disk (SSD) using a nonvolatile memory when storing data. Also, the nonvolatile memory 4100 may be provided as a fusion flash memory (e.g., a memory in which a SRAM buffer, a NAND flash memory and a NOR interface logic are combined with one another). If the RAM 4300 includes a write timing calibration acceleration circuit, a time taken to perform a write timing calibration in the computing system may be reduced or minimized. Thus, a boot up time of the computing system may be minimized and power usage and consumption may be saved. Therefore, performance of a battery operated computing system is improved.

The semiconductor memory device and/or the controller in accordance with the inventive concept can be mounted by various types of packages. For example, the semiconductor memory device and/or the controller can be mounted by various types of packages such as a PoP (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi-chip package (MCP), wafer-level fabricated package (WFP), and/or a wafer-level processed stack package (WSP) and mounted.

According to some exemplary embodiments of the inventive concept, a time taken to perform a write timing calibration in the semiconductor memory device may be reduced or minimized. Thus, a boot up time of the computing system including the semiconductor memory device may be minimized and a power may be greatly saved.

Although a few exemplary embodiments of the present general inventive concept have been shown and described, it will be appreciated by those skilled in the art that changes may be made in these exemplary embodiments without departing from the principles and spirit of the general inventive concept, the scope of which is defined in the appended claims and their equivalents. Therefore, the above-disclosed subject matter is to be considered illustrative, and not restrictive.

What is claimed is:

1. A method of performing a write timing calibration of a semiconductor memory device comprising:
detecting a phase difference between a first signal and a second signal applied for a write timing calibration; and
outputting detection information corresponding to the detected phase difference through a data output line.

2. The method of claim 1, wherein if the first signal is a data strobe signal, the second signal is a clock signal.

3. The method of claim 1, wherein if the first signal is a clock signal, the second signal is a data strobe signal.

4. The method of claim 2, wherein the data strobe signal is applied in the form of a differential signal.

5. The method of claim 4, wherein the clock signal is applied in the form of a differential signal.

6. The method of claim 5, wherein detecting the phase difference is performed using a proportional phase detection method.

7. The method of claim 6, wherein the detection data is obtained by counting the detected phase difference by a divided clock signal of the clock signal.

8. The method of claim 6, wherein the detection data is obtained by performing an analog-digital conversion on the detected phase difference by a divided clock signal of the clock signal.

9. The method of claim 7, wherein the detection data output through the data output line is binary data.

10. A write timing calibration circuit of a semiconductor memory device comprising:
a phase difference detection unit configured to detect a phase difference between a first signal and a second signal applied for a write timing calibration; and
a detection data output unit configured to output detection information corresponding to the detected phase difference through a data output line.

11. The write timing calibration circuit of claim 10, wherein the phase difference detection unit is a proportional phase difference detector.

12. The write timing calibration circuit of claim 10, wherein the detection data output unit comprises:
a counter configured to count the detected phase difference by a divided clock signal of a clock signal; and
a rate detector configured to generate the divided clock signal by dividing the clock signal.

13. The write timing calibration circuit of claim 10, wherein the detection data output unit comprises:
a dividing block configured to divide the detected phase difference by a divided clock signal of clock signal; and
a rate detector configured to generate the divided clock signal by dividing the clock signal.

14. The write timing calibration circuit of claim 10, wherein the detection data output unit comprises:
an analog-digital conversion block configured to perform an analog-digital conversion on the detected phase difference by a divided clock signal of clock signal; and
a rate detector configured to generate the divided clock signal by dividing the clock signal.

15. A method of performing a write timing calibration of a semiconductor memory device comprising:
detecting a phase difference between signals applied for a write timing calibration;
determining detection data corresponding to the detected phase difference; and
performing the write timing calibration of the semiconductor memory device using the detection data.

16. The method of claim 15, wherein the signals applied for the write timing calibration include a data strobe signal and a clock signal.

17. The method of claim 16, wherein at least one of the data strobe signal and the clock signal is applied in the form of a differential signal.

18. The method of claim 17, wherein detecting the phase difference is performed by using a proportional phase detection method.

19. The method of claim 15, wherein determining the detection data corresponding to the detected phase difference comprises counting the detected phase difference by a divided clock signal of the clock signal.

20. The method of claim 15, wherein determining the detection data corresponding to the detected phase difference comprises performing an analog-digital conversion on the detected phase difference by a divided clock signal of the clock signal.
